(19) United States
(12) Patent Application Publication
(10) Pub. No.: US 2010/0321451 A1
(43) Pub. Date: Dec. 23, 2010

(54) INK CARTRIDGE HAVING CIRCUIT BOARD ELEMENT

(75) Inventors: Lucio Bianco, Jona (CH); Daniel Sulser, Wald (CH)

Correspondence Address: MICHAEL BEST & FRIEDRICH LLP, 100 E WISCONSIN AVENUE, Suite 3300, MILWAUKEE, WI, 53202, US

(73) Assignee: PELIKAN HARDCOPY PRODUCTION AG, Egg (CH)

(21) Appl. No.: 12/867,244

(22) PCT Filed: Feb. 11, 2009
(86) PCT No.: PCT/EP09/51549

§ 371 Date: Aug. 11, 2010

(30) Foreign Application Priority Data
Feb. 15, 2008 (DE) 102008009460.9

(51) Int. Cl. B41J 2/175; H05K 1/00; H05K 13/00

(52) U.S. Cl. 347/86; 174/254; 29/592.1

(57) ABSTRACT

An ink cartridge for insertion into a cartridge receptacle of an inkjet printer, wherein the ink cartridge (10) has a circuit board element (40) including a circuit arrangement (55), said circuit board element (40) having a first subarea (41) situated in a plane A and a second subarea (42) oriented at an angle with respect to the first subarea (41).

### RELATED APPLICATIONS

This application claims priority from German Patent Application No. 10 2008 009 460.9, filed Feb. 15, 2008 and PCT Application No. PCT/EP2009/051549, filed Feb. 11, 2009, both of which are incorporated by reference herein.

### BACKGROUND

The invention relates to an ink cartridge for insertion into a cartridge receptacle of an inkjet printer and to a manufacturing method for an ink cartridge for insertion into a cartridge receptacle of an inkjet printer.

Inkjet printers belong today to the most widely used types of printers, which are employed in many home but also office applications. Since inkjet printers, during their operation, are sometimes subjected to extremely frequent use, numerous components are affected by heavy wear, and parts subject to wear as well as consumables need to be exchanged and replaced an increased number of times. The frequent use moreover requires maintenance operations to be performed at regular intervals. In order to facilitate the maintenance operations and the replacement of single components of an inkjet printer, inkjet printers are manufactured in modular construction, with a great number of modular components being provided with means which support the proper exchange, respectively cause a check of this exchange to be carried out.

Ink cartridges are typically the by far most frequently replaced components or consumables of an inkjet printer. In addition, ink cartridges also need more frequent maintenance since both the storing and the providing of the ink used during the printing sequence is a complex fluid-technological process, which can exhibit a number of sources of errors. The sources of errors, for example, can range from blocked supply ducts of the ink cartridge to incorrectly inserted ink cartridges. In addition, in view of the great multitude of different ink cartridges, it is seemingly not excluded that users, when replacing used ink cartridges, try a replacement with an ink cartridge which is not suited for insertion into a cartridge receptacle provided in the inkjet printer. Although the removal of an ink cartridge from the cartridge receptacle and the renewed insertion of same principally is a relatively simple manipulation, these manipulations may sometimes, as practice shows again and again, pose serious problems to a user.

To facilitate maintenance as well as exchange operations for the user with respect to the ink cartridges, the ink cartridges may be provided with corresponding electronic circuitries already by the manufacturer which can be addressed after correct insertion into the cartridge receptacle of an inkjet printer via a control means of the inkjet printer and which performs a check of the functionality of the ink cartridge. This check, which typically is carried out as an electronic verification routine in either active or passive form, thus can make a user sure that a cartridge has been properly inserted into the cartridge receptacle of an inkjet printer. The communication between the user and the inkjet printer ensues in this case typically via lights or via messages on a display on the printer itself. The local separation of the inserted ink cartridge and the site of information reproduction again may lead to misinterpretations or misunderstandings by the user. For this reason, the manufacturers of inkjet printers and ink cartridges have taken the constructional measure to display the information directly on the inserted ink cartridge itself. Ink cartridges known in the prior art, for instance use autonomous lighting units for this purpose, which, when the ink cartridge is inserted in the cartridge receptacle, indicate to the user that a correct insertion has been performed. On the other hand, the absence of a luminous signal at the ink cartridge may also indicate that either the insertion had not been performed correctly or another malfunction is existing.

According to the constructional design of many ink cartridges of inkjet printers, only selected areas of the ink cartridge are visible to the user in the inserted state and consequently suitable for accommodating such signal generators as, for example, lights or lamps, and displaying signals, which are easily visible to the user. Most of the areas of a housing unit of an ink cartridge in the inserted state, however, are concealed to the user. But since, on the other hand, the ink cartridge interface to the mating interface of the cartridge receptacle of the inkjet printer is for constructional reasons arranged invisible to the user, the optical signal generator of the ink cartridge needs to be connected to the interface, if necessary, over longer distances. Such a connection, especially when it is of optical nature, can entail an important expenditure in constructional and hence manufacturing technology and renders ink cartridges susceptible to numerous disturbing influences.

EP 1 547 782 A2 as a prior art publication, for example, relates to a detachably mountable ink cartridge of an inkjet printer, which, on a side adjacent to the lower boundary surface of the ink cartridge, has electrical contacts provided for establishing contact with respective mating contacts of the cartridge receptacle of the inkjet printer. The contacts in turn are mounted on a circuit board element comprising a circuit arrangement. This circuit board element includes in addition a light-emitting diode (LED) which is arranged on the surface portion adjacent to the lower boundary surface for emitting light on the circuit board element. In order to direct the light signal to a point which is visible to a user or a photodetector included in the inkjet printer, the ink cartridge provides an optical conductor oriented from the bottom to the top on the side face of the ink cartridge in the orientation of an inserted ink cartridge. The end piece of the optical conductor mounted close to the upper boundary surface of the ink cartridge is exposed and consequently suitable for unimpeded and detectable light emission.

### SUMMARY

The provision of the optical conductor of the ink cartridge according to the disclosure of EP 1 547 782 A2, however, presents numerous sources of error. On the one hand, a good optical contact needs to be made between the LED mounted on the ink cartridge and the optical conductor of the ink cartridge. This may even be affected significantly by typical contaminations such as dust or humidity and the ink itself. For unimpeded further transmitting of light, on the other hand, faults such as cracks or fractures, which are not untypical when caused by material fatigue, for example, must not be present in the optical conductor. In addition, the conditions for the presence of total reflection in the optical conductor must be guaranteed at any time. These conditions, however, can be impeded when humidity or ink is deposited which has a refraction index different from the refraction index of the optical conductor. Correspondingly, a series of typical disturbing influences are possible, which cause the emission of light by the LED to a point which is visible to the user or the photodetector to be not always guaranteed. Moreover, only a linear further transmission of light is chosen, which always requires straight or planar portions on the housing of the ink cartridge.

The task of the present invention hence is to avoid the drawbacks known from prior art in an ink cartridge according to the invention for insertion into a cartridge receptacle of an inkjet printer, and to propose an ink cartridge which allows signals, in particular signals for an optical signal, to be further transmitted from an area of the ink cartridge, which is invisible to the user, to an area which is visible to the user or a photodetector when the ink cartridge is inserted, wherein the design solution, on the one hand, is to be unsusceptible to external disturbing influences, and on the other hand, is to enable the further transmitting of signals along many subareas of the contour of the ink cartridge to a likewise wide extent.

This task is solved in particular by an ink cartridge for insertion into a cartridge receptacle of an inkjet printer, wherein the ink cartridge comprises a circuit board element having a circuit arrangement, the circuit board element having a first subarea situated in a plane A and a second subarea oriented at an angle with respect to the first subarea.

This task is further solved by an ink cartridge for insertion into a cartridge receptacle of an inkjet printer, the ink cartridge comprising a circuit board element having a circuit arrangement, wherein the circuit board element essentially extends across a side face of the ink cartridge and comprises a second subarea facing the bottom side of the ink cartridge, on which subarea contact elements are arranged for contacting to external mating contact elements, and which comprises a first subarea facing the top side of the ink cartridge and on which at least one light-emitting diode (LED) is arranged for emitting signals.

The task is in addition solved by a manufacturing method related to an ink cartridge for insertion into a cartridge receptacle of an inkjet printer, wherein the ink cartridge comprises a circuit board element having a circuit arrangement and a first subarea situated in a plane A as well as a second subarea oriented at an angle with respect to the first subarea, and wherein the method includes the following steps: providing the ink cartridge, providing the circuit board element, attaching the first subarea of the circuit board element parallel to at least one side wall, preferably a front and/or rear wall of the ink cartridge, and attaching the second subarea to the ink cartridge.

One point of the present invention consequently resides in the fact that a signal transmission can be performed by means of a circuit arrangement included in a circuit board element from a subarea of the circuit board element to a second subarea of the circuit board element, wherein the two subareas are oriented at an angle with respect to one another. It is thus provided that the signal transmission of a circuit arrangement, such as it is known, for instance, from electronic circuit engineering, but also from optical circuit engineering, be performed via two subareas of a circuit board element, wherein the circuit arrangement comprises at least one non-planar subarea to be arranged on a likewise non-planar portion of an ink cartridge.

It is true that the ink cartridges known in the prior art comprise also circuit arrangements on electronic boards or printed circuit boards, which, however, due to their high rigidity, do not allow signals to be transmitted or further transmitted via non-planar or non-angled portions of an ink cartridge. The printed circuit boards or boards for ink cartridges known from the prior art namely consist of a highly rigid material. However, for transmitting electrical or else optical signals from one subarea of a housing unit of the ink cartridge to another subarea via angled portions of an ink cartridge, interfaces are in each case required according to the knowledge of the prior art. But such interfaces always present sources of error which can prevent or else noticeably disturb a transmission of a signal free of interference. According to the core idea of the present invention, such interfaces now become unnecessary, since the circuit arrangement in its entirety enables signals to be transmitted via non-planar or angled portions of an ink cartridge between two subareas of a circuit board element oriented at an angle with respect to each other.

A further core idea of the present invention is that the circuit board element essentially extends across a side face of the ink cartridge and provides an interface for contacting, for receiving and transmitting signals, on the second subarea facing the bottom side of the ink cartridge and provides on a further subarea facing the top side of the ink cartridge, a light-emitting diode, which constitutes an optical interface for a user, respectively a photodetector used by the inkjet printer. According to the construction according to the invention, all necessary circuit arrangements for the function of the ink cartridge may consequently be accommodated on one uniform circuit board element, which is extremely cost-efficient and can be manufactured in high numbers of pieces. However, since no further measures have to be taken for a signal reception or signal emission by the ink cartridge housing, these housings, for example, may be produced in a very simple injection-molding process. Complex process steps such as the integration of optical, electronic or electrical components into the housing unit of the ink cartridge itself can consequently be omitted.

One embodiment of the ink cartridge for insertion into a cartridge receptacle provides for at least one subarea of the outer contour of the ink cartridge to be attached following the ink cartridge. This subarea may be the subarea situated in a plane A which follows, for example, a planar outer contour of the ink cartridge such as it is represented by the side wall of many commercially available ink cartridges. On the other hand, it is also conceivable for the second, not necessarily planar subarea which is oriented at an angle with respect to the first subarea, to follow a non-planar outer contour of the ink cartridge, respectively to assist in bridging a non-planar outer contour of the ink cartridge at least in part. The attachment of the circuit board element to the ink cartridge in this case may be made via one subarea or even via both subareas.

A further embodiment of the present invention may provide for the plane A to be oriented parallel to at least one side wall, preferably a front and/or rear wall. The circuit board element may thus be applied to many commercially available ink cartridges which have planar side walls arranged at least in part visible to a user or a photodetector even when the ink cartridge is already inserted into the cartridge receptacle of an inkjet printer.

In another further embodiment of the present ink cartridge, the second subarea is of planar configuration and is situated in a second plane B which is different from plane A. As a result, two planar portions, which are in each case parallel to the planes A and B, may be provided with one uniform circuit board element, for example, without interfaces being required to be provided between the two subareas of planar configuration of the circuit board element. On the contrary, circuit board elements having two planar subareas oriented at an angle with respect to each other may be prefabricated in a precisely fitting manner, so that same only have to be placed onto predetermined planar portions of the ink cartridge and be fixed to the latter.

Moreover, the ink cartridge for insertion into a cartridge receptacle may also be characterized in that the plane B is oriented parallel to a further portion of the outer boundary surface of the ink cartridge. This enables two subareas of the circuit board element arranged planar with respect to each other to be mounted in parallel orientation on the outer boundary surface of the ink cartridge, wherein only one continuous circuit board element may cover two adjacent subareas on the outer boundary surface of the ink cartridge, which are planar and arranged at an angle with respect to each other.

Another further embodiment of the ink cartridge for insertion into a cartridge receptacle may provide for the ink cartridge to comprise fastening elements, by means of which the circuit board element is attached to the ink cartridge. In this case, fastening elements in the meaning according to the embodiment, are any mechanical or adhesion-based fastening elements usual in craft. By providing the fastening elements in the structure of the housing of the ink cartridge, a circuit board element itself provided for the connection to the ink cartridge may have a simple, for example, rectangular shape. This fact in turn promotes the production of circuit board elements in large numbers of pieces and by means of industrially current manufacturing methods. As an alternative to this, it is likewise conceivable to provide special anchoring structures in the circuit board element, which, however, causes further process steps and thus costs in most of the manufacturing methods for producing larger quantities of circuit board elements.

In a further embodiment of the present ink cartridge, same may be characterized by a guiding rail, in particular on the at least one side wall, for introducing at least a part of the circuit board element. Guiding rails are simple mechanical constructional means by means of which in one connecting step, namely the insertion of the circuit board element into the guiding rail, a relatively strong and durable connection between the ink cartridge and the circuit board element can be established. According to the design, the guiding rails may already be provided in the housing unit of the ink cartridge or else may be mounted to same subsequently in a separate manufacturing step. In addition, guiding rails allow for a connection of the ink cartridge and the circuit board element without requiring further fastening methods. Furthermore, the guiding rail according to the embodiment, which alternatively may also be replaced by a plurality of guiding rails, can be arranged on the ink cartridge in such a manner that, after inserting a part of the circuit board element, the guiding forces of the guiding rail acting upon the circuit board element are directed so as to oppose a good holding force to possible stress loads of the circuit board element caused by the use or handling of the ink cartridge.

Furthermore, it can be provided for the fastening elements to comprise an elastically deformable locking hook. The locking hook may be provided alternatively or else additionally with further fastening elements. It may either be an integral part of the ink cartridge or the housing unit of the ink cartridge or else be mounted to same only subsequently in a separate manufacturing step. The locking hook may in this case be configured and mounted to the ink cartridge in a manner to engage into predetermined areas of the circuit board element, respectively to apply a locking force to the ink cartridge, so that the circuit board is connected to the ink cartridge. It is likewise possible to provide a locking hook in combination with a guiding rail for attaching the circuit board element to the ink cartridge. For doing this, it would be conceivable for the circuit board element to be initially inserted into the guiding rail at least in part, wherein the locking hook, after the circuit board element has been inserted, locks and consequently fastens same to the ink cartridge. In this case, the locking hook may either apply a holding force to one of the side walls of the circuit board element or engage into predetermined recesses, respectively appropriate shaped-part areas of the circuit board element and apply same with a corresponding holding force. It would be likewise conceivable for the circuit board element to be attached to the ink cartridge by a plurality of locking hooks, which apply holding forces to the circuit board element in a manner adapted to each other, so that a sufficient attaching to the ink cartridge takes place.

A further embodiment of the present invention may provide for the circuit board element to be detachably mounted to the ink cartridge. This results in that, on the one hand, in case of a defective circuit board element, only this element needs to be replaced in the ink cartridge, so as to produce an ink cartridge, which can still be used or sold. Furthermore, the detachable mounting of the circuit board element to the ink cartridge enables both components to be produced in respective separate, and therefore possibly more cost-efficient usual manufacturing steps. In addition, the detachable mounting of the circuit board element opens-up the option of carrying out a simplified recycling of the ink cartridge together with the circuit board element, which is a welcome aspect, especially when viewed in the light of the ink cartridge manufacturer's future responsibility. Since in contrast to ink cartridges which comprise circuit board elements in an integrated or cast-in form and thus sometimes require complex separating steps in the later recycling process, the circuit board element may be easily detached from the ink cartridge and separately disposed of according to the present embodiment.

In a further embodiment of the ink cartridge, the circuit board element may be attached to the ink cartridge by means of adhesion or lamination or fusion. These attachment methods usual in industry, which guarantee a high resistance of the connection between the circuit board element and the ink cartridge, may be carried out in a relatively uncomplicated way. Moreover, a durable and, under all operational conditions, fixed mounting of the circuit board element to the ink cartridge may be guaranteed. This fixed, virtually non-reversible connection of the circuit board element and ink cartridge moreover prevents unauthorized persons from easily removing the circuit board element from the ink cartridge and manipulating it unimpeded. As to an adhesion of the circuit board and the ink cartridge, any adhesives usual in commerce and industry may be used, insofar as they are suitable for adhering the surfaces intended for being connected to one another.

A further embodiment of the circuit board element comprising a circuit arrangement for connecting to an ink cartridge provided for insertion into a cartridge receptacle of an inkjet printer, may provide for the circuit board element to comprise at least one first subarea situated in a plane A and a second subarea oriented at an angle with respect to the first subarea. As a result, the circuit board element may also be used in conjunction with ink cartridges, the outer contour of which does not merely have a planar surface portion. According to the present embodiment, the circuit board element on the contrary may be mounted to bent surface portions or else to surface portions extending in a slope with respect to each other. A slope in the present meaning is a non-planar continuous area, which comprises two substantially planar, at least locally planar, and contiguous sections or surface portions, the mutual orientations of which define a limit angle unequal to 180 degrees. The limit angle, in turn, is defined as the angle between the normal of the section or surface portion.

A further embodiment of the subject matter according to the invention may likewise provide for a connecting portion to be provided between the second subarea and the first subarea of the circuit board element, which defines a flexible area of the circuit board element. This flexible area, which preferably is configured to be flexible, thus allows an adaptable mounting of the circuit board element to non-planar portions of the ink cartridge, by firstly mounting a subarea of the circuit board element to the ink cartridge, and guiding the further subarea, after a bending process of the flexible area, to the outer contour of the ink cartridge so that it can also be attached to the ink cartridge or parallel thereto. Moreover, the provision of a flexible area of the circuit board element also allows for a flexible adaptation to different subareas of ink cartridges differing from each other. Consequently, a circuit board element according to the embodiment occasionally may also be provided for a series of different ink cartridges, without requiring a circuit board element deviating in its construction. The direct consequence thereof is a saving in constructional, manufacturing technology and economic expenditures.

Furthermore, it is also possible for the circuit board element for connecting to an ink cartridge to be implemented so that the connecting portion has conductor tracks. The conductor tracks, as a constituent of the circuit arrangement included in the circuit board element, according to the embodiment allow a direct connection of the first and the second subareas of the circuit board element, without these being required to be connected directly adjacent to one another. Conductor tracks such as, for instance, produced in a photolithographic method with a subsequent etching method, are characterized by high flexibility. Accordingly, it is not unusual that conductor tracks can also be applied to a flexible substrate without compromising the integrity of the circuit arrangement in which the conductor tracks are included. Thus, an advantageous connecting construction of the two subareas is also possible in the present case while profiting from all of the advantages of the described conductor tracks. According to the embodiment, the conductor tracks, in addition, are not exclusively restricted to electrical or electronic conductor tracks. Rather, flexible optical conductor tracks are likewise conceivable, provided, these fulfill the requirements of flexibility of the connecting portion.

In a still further embodiment of the present subject matter, the second subarea of the circuit board element may have contact elements, which are capable of establishing an electrical contact with corresponding mating contact elements of the cartridge receptacle of the inkjet printer when the ink cartridge is inserted into the cartridge receptacle of the inkjet printer. Accordingly, the contact elements represent the interface to the at least one circuit arrangement on the circuit board element. The contact elements are preferably shaped so as to correspond to the geometry of the mating contact elements as a mirror image. The contact elements of the second subarea may be implemented as conventional electrical contacts or else as optical contacts for transmitting optical signals.

In a further embodiment of the circuit board element, the circuit board element may have a first layer comprising the circuit arrangement and a second layer imparting stability to the circuit board element. As an alternative, the circuit board element may also have a higher number of successive layers. In such a case, the circuit arrangement may then be arbitrarily disposed on a layer which is suited for it. Such sequences of layers typically are formed in photolithographic methods for imaging circuit arrangements by means of a series of chemical and physical steps. Typically in this case, an image of the circuit arrangement is applied to a superficial layer of the circuit board blank by means of photographic copying and developed by an etching process. The second layer imparting stability to the circuit board element according to the embodiment, may comprise any material of corresponding rigidity and resistance. Typical suitable materials are plastics or resins of all kinds. In addition, for electrical or electronic circuit arrangements it is also of importance for the second layer imparting resistance to the circuit board element also to have isolating properties. When a purely optical circuit arrangement is provided, such restrictions are not imperative.

According to a further embodiment of the circuit board element for connecting to an ink cartridge, the second layer in the connecting portion may be at least thinned. Accordingly, the connecting portion does not exhibit the complete resistance imparted by the second layer, and has, for example, a higher flexibility to bending in comparison to other subareas of the circuit board element. By making the second layer in the connecting portion thinner, hence by correspondingly selecting the layer thickness, the flexibility, respectively flexural rigidity of the connecting portion may be made variable. In addition, by correspondingly configuring the thinning of the connecting portion, further areas of the circuit board element may be created, into which the fastening elements of the ink cartridge may engage, respectively apply a holding force thereto.

The circuit board element for connecting to an ink cartridge in a further embodiment may also provide for the second layer imparting resistance to the circuit board element, to be removed in the connecting portion. Correspondingly, the connecting portion is only formed by the first layer which may comprise parts of the circuit arrangement. By removing the second layer, the stability and flexibility of the connecting portion is determined completely by the first layer. With an inappropriate handling of the circuit board element, this circumstance may contribute to an inadvertent damage of the circuit board element, these disadvantages, however, are balanced by the advantages of manufacturing technology which result from simply removing the second layer in the connecting portion.

In a further embodiment of the circuit board element for connecting to an ink cartridge, the former may have further contact points provided for contacting an external electrical interface, via which, after an electrical contact is established, information data or signals may be transmitted to or exchanged with the circuit arrangement disposed on the first layer. Operational parameters of the circuit arrangement, for instance, may be read out via contact points of this type by means of an external reading device, when required. It is, however, by far more relevant to supply programmable circuit elements of the circuit arrangement with data via the contact points, and to program same according to predetermined data for providing a specific functionality of the circuit board and the ink cartridge. Thus, for example, physical or logistic parameters characterizing the ink cartridge may be read in on the circuit board element, which may otherwise be read out or processed in terms of control technology for the identification of the ink cartridge, respectively the status thereof. For possibly preventing unintentional overwriting or deleting of data, contact points may be provided, via which only reading-out of information is possible. Other contact points, for example, may be provided specifically for programming the circuit arrangement of the circuit board element. The provision of further contact points on the circuit board element for transmitting or exchanging data or signals with the circuit arrangement consequently allows a wide spectrum of options for individualizing the circuit board element for an ink cartridge having improved functionality.

Another embodiment of the present subject matter of the invention may in addition provide for the circuit board element to comprise at least one light-emitting diode (LED). By providing at least one light-emitting diode as a circuit element of the circuit arrangement, the functionality of the circuit board element comprising the light-emitting diode is increased to the extent that upon corresponding control signals of the circuit control, light signals are emitted to the outside which can be observed by a user or picked up by a photodetector. Accordingly, a user, respectively a control device interacting with a photodetector can perceive predefined circuit conditions of the circuit arrangement on the circuit board element by means of perceived light signals. The light signals of the light-emitting diode caused by predetermined control signals of the circuit arrangement may in case of an appropriate control furnish information on the functional states of the ink cartridge, malfunctions, or else emit light signals relevant for servicing the ink cartridge. Consequently, the maintainability is increased and the direct verifiability of the functional state of the ink cartridge made possible.

According to a further embodiment of the present ink cartridge for insertion into a cartridge receptacle, it can be provided for the contact elements to be arranged essentially at an end position on the second subarea of the circuit board element. The end-position arrangement correspondingly facilitates the establishing of contact by the contact elements with the mating contact elements included in the cartridge receptacle. An end-position arrangement of the contact elements, in addition, avoids the providing of unnecessary surface portions of the circuit board element.

The circuit board element may further provide for at least one light-emitting diode (LED) to be arranged on the first subarea of the circuit board element. Consequently, the at least one light-emitting diode is capable of radiating light having a preferential direction relative to the first subarea, independent of the orientation of the second subarea of the circuit board element. The direction of the irradiated light is therefore independent of the second subarea of the circuit board element and the orientation thereof.

A further embodiment of the circuit board element for connecting to an ink cartridge may provide for at least one light-emitting diode (LED) to be arranged essentially at an end position on the first subarea of the circuit board element. In the case that the light irradiated by the light-emitting diode is picked up by a photodetector and transferred to a further control device or recording device, the end-position arrangement of the light-emitting diode allows a relatively undisturbed picking up. Moreover, the picking up is enabled from an increased solid angle range. This is also true for a user, who is able to observe the light of the light-emitting diode from an increased solid angle range relative to the first subarea.

A further embodiment of the circuit board element for connecting to an ink cartridge provides for at least one light-emitting diode (LED) to be arranged in the circuit board element in such a manner that the light irradiated by the light-emitting diode (LED) upon activation is irradiated unimpeded by the ink cartridge, in particular perpendicular to the plane A of the circuit board element. Accordingly, it is possible to detect by means of further technical devices such as a photodetector, for example, the light irradiated by the light-emitting diode in unimpeded intensity and to process the detected signal possibly in a further control process. Furthermore, the unimpeded irradiation of the light of the light-emitting diode facilitates the optical perception by a user, who is able to perceive the light in its full intensity.

It may further be provided for the circuit arrangement of the circuit board element to be suited to process the signals received from an external control of the inkjet printer via the contact elements and, upon a corresponding request, execute a verification routine, which allows a verification of the ink cartridge connected to the circuit board element. The circuit arrangement is consequently constructed so as to be capable of checking by means of a verification routine, whether a proper ink cartridge had been correctly inserted into the cartridge receptacle and is also ready for printing. Verification routines of this kind may further comprise more test algorithms which also check other aspects of the functionality of the ink cartridge such as, e.g., the filling level.

A further embodiment of the ink cartridge may moreover provide for the circuit arrangement, after the verification routine has been run, to allow the emission of a light signal by the light-emitting diode (LED) on the circuit board element. A user may in this manner be informed that a certain ink cartridge has reached a predetermined functional or test state. Depending on the signal emission with signals of predetermined signal identifiers, a positive as well as a negative feedback may be conveyed to the user. It is moreover conceivable for signals having determined identifiers to also indicate a specific functional state, which does not only show the printing readiness of the ink cartridge. Consequently, signals with respect to the actual filling state of the ink cartridge or functional states of the printing head cooperating with the ink cartridge may also be conveyed.

Alternative to this, it is also possible for the circuit arrangement, after the verification routine has been run, to prevent the emission of a light signal by the light-emitting diode (LED) on the circuit board element, if the result of the verification routine is negative. Accordingly, an absence of a light signal possibly expected by a user, also includes information on the functionality, respectively the functional state of the ink cartridge. For example, after successfully inserting an ink cartridge into the cartridge receptacle of the inkjet printer, a user namely expects the functionality of the ink cartridge in all its functions to be clearly indicated by one or more light signals. If a light signal, in contrast, fails unexpectedly, the user is informed that either the functionality of the ink cartridge is not given or else another problem with respect to an undisturbed functionality of the ink cartridge exists.

The invention is explained in the following in terms of exemplary embodiments which are explained in more detail by means of the Figures.

### BRIEF DESCRIPTION OF THE DRAWINGS

FIG. 1 an embodiment of an ink cartridge according to the invention for insertion into a cartridge receptacle of an inkjet printer, in a perspective side view.

FIG. 2 the ink cartridge as per FIG. 1 for insertion into a cartridge receptacle, in a side view,

FIG. 3 an ink cartridge for insertion into a cartridge receptacle according to the preceding Figures, in a front view,

FIG. 4 an embodiment of the circuit board element for connecting to an ink cartridge, in an two-dimensional top view from above,

FIG. 5 the circuit board element for connecting to an ink cartridge as per FIG. 4, in a side view, and

FIG. 6 the circuit board element for connecting to an ink cartridge illustrated in FIG. 5 and FIG. 4, with the first and second subareas of the circuit board element being at an angle with respect to each other.

For identical parts or parts of equal action, the same reference numerals will be used in the following description.

### DETAILED DESCRIPTION

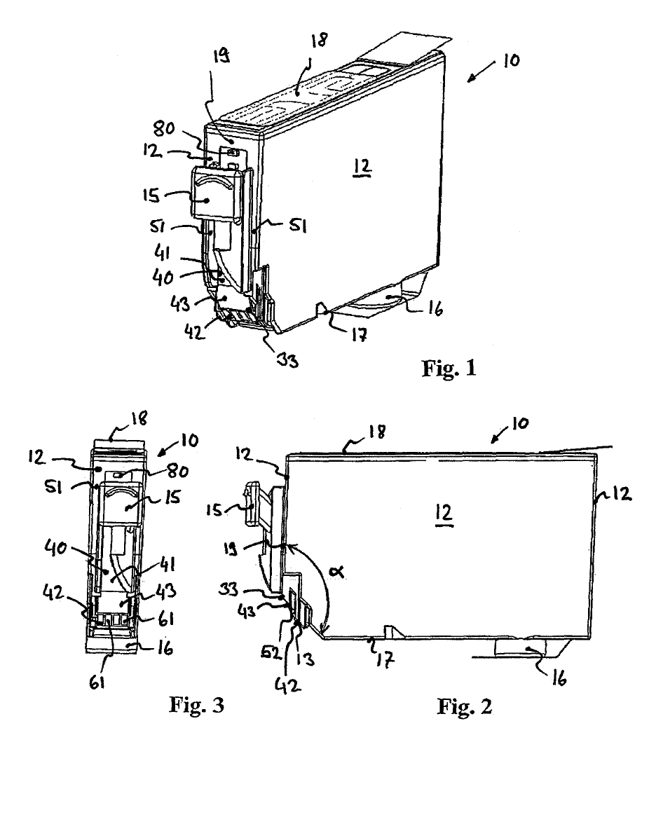

FIG. 1 shows an embodiment of the ink cartridge according to the invention for insertion into a cartridge receptacle of an inkjet printer, the housing of which is of an essentially right parallelepiped construction. The housing of the ink cartridge 10 comprises four side walls 12 in total, of which, due to the perspective representation, only one front wall 19 and a large-surface side wall 12 following this side wall 19 are shown. Both sidewalls 12 are delimited upward by the top side 18 and downward by the bottom side 17 and are connected to same according to the present orientation of the ink cartridge. All of the side walls 12 together with the bottom side 17 and the top side 18 define an ink cartridge volume, in which ink for the printing process is stored.

The ink cartridge further comprises a locking catch 15 which during the insertion of the ink cartridge 10 into a cartridge receptacle, not shown in more detail, of the inkjet printer tightly locks the ink cartridge in the cartridge receptacle and thus prevents the ink cartridge 10 from being unintentionally released from the cartridge receptacle.

The ink cartridge 10 moreover comprises on the front wall 19, a guiding rail 51, which extends in the illustrated orientation of the ink cartridge at the right and left outer edges of the front wall 19 from the bottom to the top. The guiding rail 51 accordingly is formed by two grooves integrated into the housing of the ink cartridge 10 which extend as described at the right and left outer edges of the front wall 19 and allow a circuit board element 40 to be inserted into the grooves from the bottom to the top, in order to attach the circuit board element 40 to the ink cartridge 10. In the present case, the circuit board element 40 is inserted into the guiding rail 51 over the entire length thereof, wherein a further upward insertion of the circuit board element 40 is prevented by a stop element such as, for example, a material protrusion from the front wall 19 or, as in the present case, by a crossbar which connects the two grooves forming the guiding rail 51 to the top towards the top side 18. The circuit board element 40 is in the present case inserted into the guiding rail 51 essentially over the entire height extension of the first subarea 41 (according to the orientations illustrated here). The second subarea 42 of the circuit board element is in the present case arranged at a portion of the ink cartridge 10 which obliquely connects the front wall 19 and the bottom side 17 which are located essentially in a right angle with respect to each other. This portion together with the front wall 19 forms a slope 33 in the meaning defined above.

The slope which is formed by the designated portion along with the front wall 19 can be particularly well seen in FIG. 2. In this case, however, one can also see that the designated portion which connects the front wall 19 and the bottom side 17 of the ink cartridge 10 which lie essentially perpendicular to each other, is not to be understood as a continuous or even only planar surface section. Rather, the portion exhibits planar and continuous surface sections only in some areas which, however, are connected to each other by the housing structure of the ink cartridge 10 and are configured to accommodate, respectively attach the second subarea 42 of the circuit board element. The attaching of the circuit board element 40 is performed in the present case by a locking hook 52, which engages into a depression intended for this purpose between the second subarea 42 and the connecting portion 43. The circuit board element 40 accordingly is secured against an unintentional releasing from the guiding rail 51 toward the bottom (according to the orientations illustrated here) by the locking hook 52 which applies a corresponding holding force to the circuit board element 40.

FIG. 3 shows a front view of the ink cartridge 10 in which the present proportions of the circuit board element 40 as well as of the guiding rail 51 are illustrated once again more distinctly. It can be seen clearly that the second subarea 42 of the circuit board element 40 has four contact elements 61 in total via which the circuit arrangement 55 (not shown here) present on the circuit board element 40 is able to communicate with an interface, not shown in more detail, of the cartridge receptacle of the inkjet printer. In the present case, only two of the contact elements 61 are provided with reference numerals so as not to disturb the clarity of representation.

The second subarea 42 is constructively connected to the first subarea 41 via the connecting portion 43. The first subarea 41 is completely inserted into the guiding rail 51 over its entire presently illustrated height extension. The grooves of the guiding rail 51 can be clearly seen, which are each mounted at the right and left of the front wall 19 and comprise the lateral terminal edges of the circuit board element 40 and consequently fix the circuit board element 40 to the front wall 19.

In the present case, the circuit board element 40 had been inserted into, respectively is fixed by the guiding rail 51 in such a manner that a light-emitting diode (LED) 80 is situated at the upper edge of the front wall 19. The light-emitting diode 80 is positioned, on the one hand, relative to a perpendicular line of sight to the front wall 19 so as not to be covered by the locking catch 15 nor, on the other hand, by the crossbar terminating the front wall 19 toward the top, which connects the two grooves of the guiding rail 51 disposed at the right and left of the front wall 19.

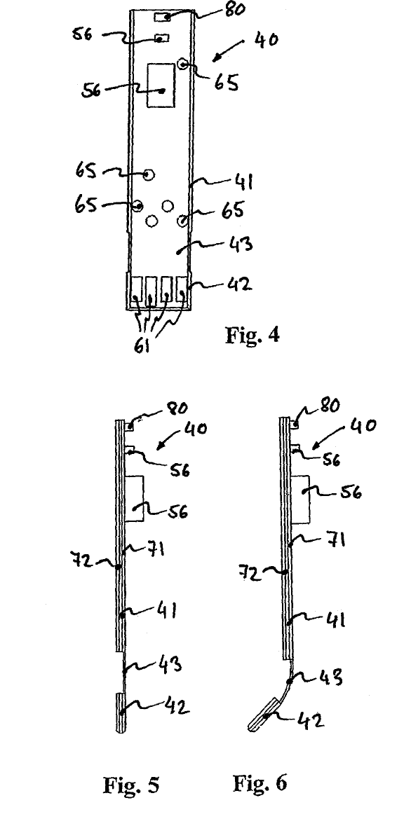

FIG. 4 shows a top view of the circuit board element 40 inserted into the ink cartridge as per FIGS. 1 to 3. The circuit board element 40 is divided into three parts, a first subarea 41, a second subarea 42, and a connecting area 43 connecting the two subareas 41 and 42. The upside-down extension of the second subarea 42 (according to the present representation) corresponds approximately to the height extension of the connecting portion 43. The height extension of the second subarea 42 illustrated here and connecting portion 43, however, are distinctly inferior than the height extension of the first subarea 41. All of the three subareas or portions illustrated here comprise a circuit arrangement 55 on the side facing the observer which, however, is not shown in detail in the present case and therefore is not provided with reference numerals. All the same, circuit elements 56 arranged on the first subarea 41 can be clearly seen. According to a specific configuration of the circuit board element 40, these can be, for example, conventional circuit elements such as resistors, capacitors or bridges, but semiconductor circuit elements or integrated circuit elements may also be provided.

The present circuit arrangement 55 transmits, respectively receives information data and signals via the contact elements 61, which represent the electrical interface relative to the circuit board element 40. The contact elements 61 may be contacted with mating contact elements, not shown in more detail, of a cartridge receptacle of an inkjet printer, and consequently addressed by a control device of the inkjet printer, respectively transmit signals to the control device. The contact elements 61 in the present case are arranged on the side of the second subarea 42 facing the observer which, as can be seen in the preceding Figures, is mounted, after the circuit board element 40 is adequately attached to the ink cartridge 10, on the portion of the ink cartridge connecting the front wall 19 to the bottom side 17 of the ink cartridge 10 via a slope 33. The slope, here in FIG. 2 relevant for attaching the circuit board element 40 to the ink cartridge 10, comprises, in the side view illustrated in FIG. 2, an angle α of about 135 degrees.

Further elements of the circuit arrangement 55 are the contact points 65, which are arranged on the first subarea 41 of the circuit board element 40. In this case, six contacts points 65 are illustrated in total which are not in a directly obvious geometric relationship to one another. The arrangement of the contact points 65, on the one hand, allows for the secure recognition and identification of a predetermined contact point 65 due to the absence of a regular arrangement. In addition, it is possible for the arrangement of the contact points 65 to be implemented so as to be able to be conveniently tapped by an external interface using correspondingly arranged mating contact points.

The circuit board element 44 moreover comprises a light-emitting diode 80 arranged at the upper (according to the present representation) terminal edge of the circuit board element 40 in the first subarea 41. According to this arrangement, the light-emitting diode 80 is enabled, as already explained in conjunction with FIG. 3, to irradiate light unimpeded related to a line of sight extending perpendicular to the illustrated surface of the first subarea 41. The light irradiated by the light-emitting diode 80 accordingly may be picked up, correspondingly processed and interpreted either by a user or else a photodetector in an unattenuated manner.

FIG. 5 shows the circuit board element 40 as per FIG. 4 in a side view. The division of the circuit board element 40 into three parts, the first subarea 41, the second subarea 42 and the connecting portion 43 can be clearly seen. The connecting portion 43 clearly thinned in its thickness connects in this case the first subarea 41 arranged above to the second subarea 42 arranged below, which both have a clearly more important thickness (side extension according to the representation) in comparison to the connecting portion 43. In this case, the two subareas 41 and 42 each comprise three material layers in total, the first layer 71 of which arranged at the right side (according to the present representation) serves for accommodating the circuit elements 56 and the light-emitting diode 80. The connecting portion 43 is moreover configured so as to comprise at least a part of the first layer 71. The thickness of the connecting portion 43 may in this case match the thickness of the first layer 71 or else be thinner than same. The further two layers of the first and second subareas 41 and 42 impart rigidity to the subareas 41 and 42 as well as protection against inadvertent damage to the circuit arrangement 55 by external mechanical influences. The two layers, which together define the second layer 72 in the present case, may in turn contain further sublayers or, as an alternative, consist of only one layer. Typical materials used for the second layer 72 are resins, plastics, as well as any isolating materials having high material rigidity.

FIG. 6 shows the circuit board element 40 already shown in FIG. 5, as it would be present. For example, when it is inserted into the ink cartridge 10 illustrated in FIGS. 1 to 3. The connecting potion 43 which in FIGS. 1 to 3 is arranged in the area of the slope 33, comprises a curvature as a result of a bending process. In this case, the respective planar subareas 41 and 42 are oriented relative to each other so that their lateral boundary lines are neither parallel nor aligned to each other, i.e., the surface portions of the subareas 41 and 42 hence are oriented at an angle to each other. The orientation shown in FIG. 6 of the first subarea 41 relative to the second subarea 42, however, is not required to result from a bending process concerning the connecting portion 43, but may alternatively be already produced in such a shape in a corresponding manufacturing method. The demands placed on the flexibility of the connecting portion 43 therefore may differ in this case according to different constructional characteristics of the connecting portion 43.

At this point, it should be pointed out that all of the parts described above taken alone or in any combination, in particular the details illustrated in the drawings, are claimed as being invention-relevant. Modifications thereof are well known to the skilled person.

1.-24. (canceled)

25. An ink cartridge (10) for insertion into a cartridge receptacle of an inkjet printer, the ink cartridge comprising:
a circuit board element (40) including a circuit arrangement (55), a first area (41) situated in a plane A, a second subarea (42) oriented at an angle with respect to the first subarea (41), a first layer (71) including the circuit arrangement (55), a second layer (72) imparting stability to the circuit board element (40), a connecting portion (43) between the second subarea (42) and the first subarea (41) of the circuit board element (40), and
wherein the connecting portion (43) defines a flexible area of the circuit board element (40) and in which the second layer (72) is at least thinned.

26. The ink cartridge according to claim 25, wherein at least one subarea (41, 42) is attached to the ink cartridge following an outer contour of the ink cartridge (10).

27. The ink cartridge according to claim 25, wherein the plane A is oriented parallel to at least one side wall (12) of the ink cartridge.

28. The ink cartridge according to claim 25, wherein the second subarea (42) is of planar configuration and is situated in a second plane B which is different from plane A.

29. The ink cartridge according to claim 28, wherein the plane B is oriented parallel to a further portion (13) of an outer boundary surface of the ink cartridge (10).

30. The ink cartridge according to claim 25, further comprising fastening elements (50), by means of which the circuit board element (40) is attached to the ink cartridge (10).

31. The ink cartridge according to claim 30, wherein the fastening elements (50) include a guiding rail (51) on the at least one side wall (12) of the ink cartridge for introducing at least a part of the circuit board element (40).

32. The ink cartridge according to claim 30, wherein the fastening elements (50) include an elastically deformable locking hook (52).

33. The ink cartridge according to claim 25, wherein the circuit board element (40) is detachably mounted to the ink cartridge (10).

34. The ink cartridge according to claim 33, wherein the circuit board element (40) is mounted to the ink cartridge by at least one of adhesion, lamination, and fusion.

35. A circuit board element for connecting to an ink cartridge, which is provided for insertion into a cartridge receptacle of an inkjet printer, the circuit board element (40) comprising:
at least one circuit arrangement (55);
at least one first area (41) situated in a plane A;
a second subarea (42) oriented at an angle with respect to the first subarea (41);
a first layer (71) including the circuit arrangement (55);
a second layer (72) imparting stability to the circuit board element (40); and
a connecting portion (43) between the second subarea (42) and the first subarea (41) of the circuit board element (40) that defines a flexible area of the circuit board element (40) and in which the second layer (72) is at least thinned.

36. The circuit board element according to claim 35, wherein the connecting portion (43) includes conductor tracks (53).

37. The circuit board element according to claim 35, wherein the second subarea (42) of the circuit boars element (40) includes contact elements (61) which are configured to make electrical contact with corresponding mating contact elements of the cartridge receptacle of the inkjet printer when the ink cartridge (10) is inserted into the cartridge receptacle of the inkjet printer.

38. The circuit board element according to claim 35, wherein the second layer (72) that imparts stability to the circuit board element (40) is removed in the connecting portion (43).

39. The circuit board element according to claim 35, further comprising contact points (65) configured to contact an external electrical interface (66) via which, after an electrical contact is established, at least one of information data and signals may be transmitted to the circuit arrangement (55) disposed on the first layer (71).

40. The circuit board element according to claim 35, further comprising at least one light-emitting diode (LED) (80).

41. The circuit board element according to claim 37, wherein the contact elements (61) are arranged at an end position on the second subarea (42) of the circuit board element (40).

42. The circuit board element according to claim 35, further comprising at least one light-emitting diode (LED) (80) that is arranged on the first subarea (41) of the circuit board element (40).

43. The circuit board element according to claim 35, further comprising at least one light-emitting diode (LED) (80) that is arranged at an end position on the first subarea (41) of the circuit board element (40).

44. The circuit board element according to claim 35, further comprising at least one light-emitting diode (LED) (80) that is arranged on the circuit board element (40) in such a manner that the light irradiated by the light-emitting diode (LED) (80) upon activation is irradiated unimpeded by the ink cartridge (10) perpendicular to the plane A of the circuit board element (40).

45. The circuit board element according to claim 37, wherein the circuit arrangement (55) of the circuit board element (40) is configured to process the signals received from an external control of the inkjet printer (10) via the contact elements (61) and, upon a corresponding request, execute a verification routine which allows a verification of the ink cartridge (10) connected to the circuit board element (40).

46. The circuit board element according to claim 45, wherein after the verification routine has been run, the circuit arrangement (55) allows the emission of a light signal by a light-emitting diode (LED) (80) on the circuit board element (40).

47. The circuit board element according to claim 46, wherein after the verification routine has been run, the circuit arrangement (55) prevents the emission of a light signal by the light-emitting diode (LED) (80) on the circuit board element (40) if the result of the verification routine is negative.

48. A method for manufacturing an ink cartridge for insertion into a cartridge receptacle of an inkjet printer comprising:
providing an ink cartridge (10);
providing a circuit board element (40) having a circuit arrangement (55) which has a first subarea (41) situated in a plane A, a second subarea (42) oriented at an angle with respect to the first subarea (41), a first layer (71) including the circuit arrangement (55), a second layer (72) imparting stability to the circuit board element (40), and a connecting portion between the second subarea (42) and the first subarea (41) of the circuit board element (40) that defines a flexible area of the circuit board element (40) and in which the second layer (72) is at least thinned; and
attaching the first subarea (41) of the circuit board element (40) parallel to at least one side wall of the ink cartridge (10); and
bending the connecting portion (43) and attaching the second subarea (42) to the ink cartridge (10).
